(19) United States
(12) Patent Application Publication
(10) Pub. No.: US 2007/0137685 A1
(43) Pub. Date: Jun. 21, 2007

(54) Solar power-operated cooling helmet

(76) Inventors: Ching-Song Jwo, Taipei City (TW); Chao-Chun Chien, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/312,753

(22) Filed: Dec. 21, 2005

(51) Int. Cl. H01L 35/28; H02N 6/00

(52) U.S. Cl. 136/203; 136/244; 136/291

(57) ABSTRACT

A solar power-operated cooling helmet is disclosed to include a helmet body, a flat solar cell module mounted in the top wall of the helmet body for converting the energy of sunlight into electric energy, a thermoelectric cooling module mounted in the helmet and electrically connected to the power output terminal of the solar cell module with a heat sink bonded to the hot side thereof and exposed to the outside of the helmet body and a cooling-air radiator bonded to the cold side and suspending inside the helmet body, and a fan-based cooling air delivery mounted inside the helmet body for delivering cold air to the inside space of the helmet body to comfort the user's head.

### BACKGROUND OF THE INVENTION

1. Field of the Invention

The present invention relates to a helmet and more particularly, to a solar power-operated cooling helmet, which uses a solar cell module to convert the energy of sunlight into electric energy for driving a thermoelectric cooling module and a mini fan-based cold air delivery unit to keep the inside space of the helmet body cool.

2. Description of the Related Art

It is a regulation law in most countries around the world that every motorcyclist must wear a helmet when riding a motorcycle. There are also regulations that request every person to wear a helmet when working in or visiting a construction, factory, or other specific places. A motorcyclist helmet protects the motorcyclist. However, it is uncomfortable to wear a motorcyclist helmet. When wearing a full-face type motorcyclist helmet during a hot day, the inside space of the motorcyclist helmet is kept in an airtight status. At this time, the motorcyclist helmet is like a baking oven that keeps hot air on the inside.

In order to eliminate the aforesaid problem, ventilation helmets are developed. There are ventilation helmets that use means to guide outside cooling air into the inside space of the helmet. However, when the speed of the motorcycle surpassed a predetermined level, a turbulent flow will be produced, resulting in a high noise. This high noise may cause the motorcyclist to feel uncomfortable or threaten the riding safety.

There is known a ventilation helmet that uses a mini motor to rotate a fan, thereby inducing currents of air in the inside space of the helmet body. There is also known a ventilation helmet that uses a thermoelectric cooler to provide cold air to the inside space of the helmet body. However, the use of a fan and motor assembly or a thermoelectric cooler in a helmet must consider the arrangement of power supply and the installation space in the helmet body. Conventional designs use the battery of the motorcycle or a storage battery to provide the necessary working voltage to the fan and motor assembly or thermoelectric cooler. These conventional designs are still not satisfactory in function.

### SUMMARY OF THE INVENTION

The present invention has been accomplished under the circumstances in view. It is the main object of the present invention to provide a solar power-operated cooling helmet, which uses a solar cell module to convert the energy of sunlight into electric energy for driving a thermoelectric cooling module and a mini fan-based cold air delivery unit to keep the inside space of the helmet body cool. It is another object of the present invention to provide a solar power-operated cooling helmet, which uses an auto switch to automatically control the operation of the thermoelectric cooling module subject to the intensity of the light of the sun.

To achieve these and other objects of the present invention, the solar power-operated cooling helmet comprises a helmet body, which has an inner lining mounted in the inside wall thereof; a flat solar cell module, which is mounted in the top wall of the helmet body, comprising a silicon chip adapted to convert the energy of sunlight into electric energy; a thermoelectric cooling module, which is mounted in the helmet body, comprising a thermoelectric cooling chip electrically connected to the power output terminal, the thermoelectric cooling chip having a hot side exposed to the outside of the helmet body and a cold side suspending inside the helmet body, a heat sink bonded to the hot side of the thermoelectric cooling chip, and a cooling-air radiator bonded to the cold side of the thermoelectric cooling chip; a cooling air delivery unit, which is mounted inside the inner lining of the helmet body, comprising a main conduit mounted inside the inner lining around the inside wall of the helmet body, a mini fan electrically connected to the power output terminal of the thermoelectric cooling module adjacent to the cold-air radiator and adapted to induce cold air toward the main conduit, and a plurality of manifolds respectively extending from the main conduit and adapted to deliver cold air from the main conduit to the inside space of the helmet body; and an auto switch installed in the power output terminal of the solar cell module and adapted to detect the current/voltage level at the power output terminal and to control the supply of electric energy from the power output terminal to the thermoelectric cooling chip and the mini fan subject to the detection result.

### BRIEF DESCRIPTION OF THE DRAWINGS

FIG. 1 is an exploded view of a solar power-operated cooling helmet according to the present invention.

FIG. 2 is a perspective assembly view of the solar power-operated cooling helmet according to the present invention.

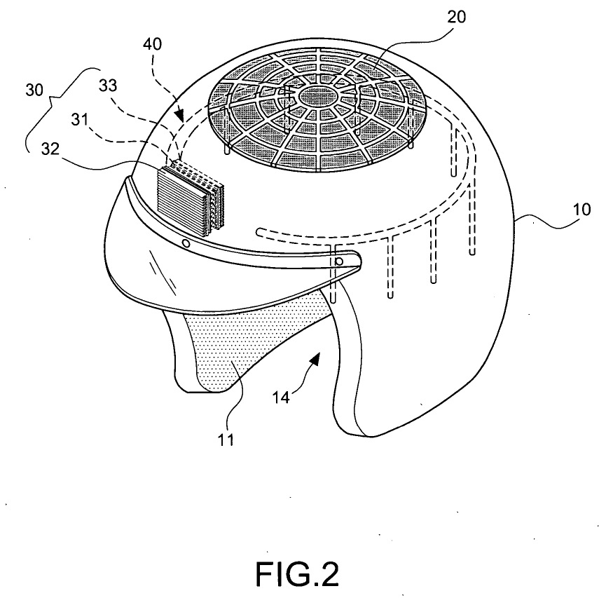

FIG. 3 is a schematic drawing showing the supply of electric energy in the solar power-operated cooling helmet according to the present invention.

FIG. 4 is a sectional view of the solar power-operated cooling helmet according to the present invention.

FIG. 5 shows an alternate form of the solar power-operated cooling helmet according to the present invention.

### DETAILED DESCRIPTION OF THE PREFERRED EMBODIMENT

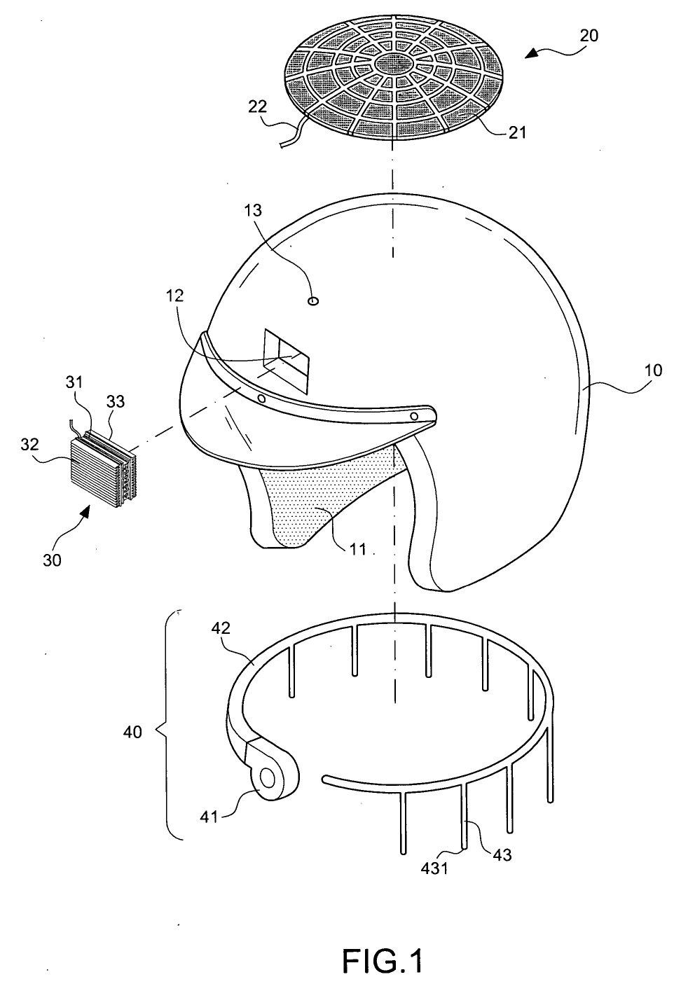

Referring to FIGS. 1˜4, a solar power-operated cooling helmet in accordance with the present invention is shown comprising a helmet body 10, a solar cell module 20, a thermoelectric cooling module 30, and a cooling air delivery unit 40.

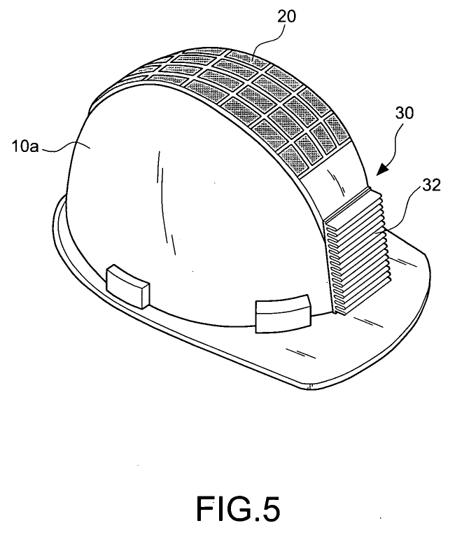

The helmet body 10 can be made in any of a variety of forms and shapes, for example, the form of a motorcyclist helmet as shown in FIGS. 1˜4, or the form of an engineer helmet 10a as shown in FIG. 5. The helmet body 10 has an inner lining 11 made of sponge or foam material that buffers impact and provides a space for accommodating the cooling air delivery unit 40.

The solar cell module 20 is preferably made subject to the shape and size of the helmet body 10. According to this embodiment, the solar cell module 20 is a flat member mounted in the top wall of the helmet body 10, comprising a silicon chip 21 adapted to convert photons of the sun into electric energy for producing electric current, and a power output terminal 22 for power output. The power output terminal 22 according to this embodiment is inserted through a through hole 13 at the helmet body 10 into the inside of the inner lining 11 to provide the necessary working voltage to the thermoelectric cooling module 30 and the cooling air delivery unit 40.

The thermoelectric cooling module 30 comprises a thermoelectric cooling chip 31, a heat sink 32, and a cooling-air radiator 33. The thermoelectric cooling module 30 is installed in the helmet body 10, preferably in a front opening 12 at the helmet body 10. After installation of the thermoelectric cooling module 30 in the front opening 12 at the helmet body 10, the hot side of the thermoelectric cooling chip 31 is kept outside the helmet body 10, and the cold side of the thermoelectric cooling chip 31 is kept inside the helmet body 10. The heat sink 32 is bonded to the hot side of the thermoelectric cooling chip 31 and adapted to make a heat exchange with the outside air for enabling heat energy to be quickly dissipated from the hot side of the thermoelectric cooling chip 31 into the outside air. The cooling-air radiator 33 is bonded to the cold side of the thermoelectric cooling chip 31. Further, the thermoelectric cooling chip 31 is electrically connected to the power output terminal 22 of the solar cell module 20.

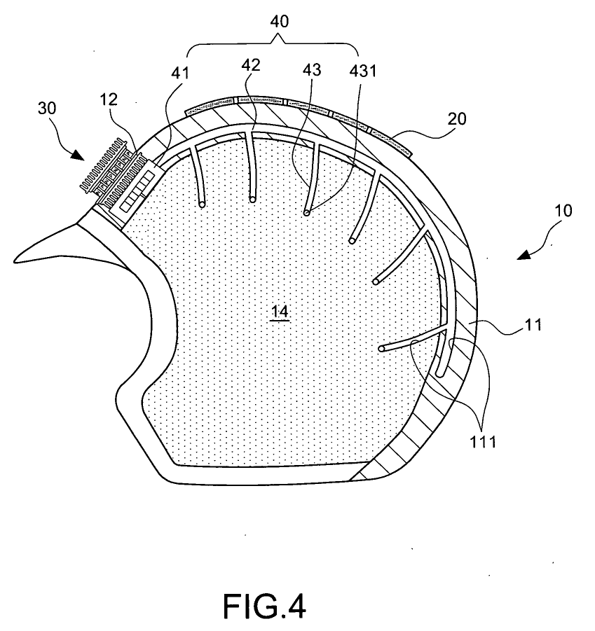

The cooling air delivery unit 40 is mounted in an accommodating chamber 41 inside the inner lining 11, as shown in FIG. 4. The cooling air delivery unit 40 comprises a mini fan 41, a main conduit 42, and a plurality of manifolds 43. The mini fan 41 is electrically connected to the power output terminal 22 of the solar cell module 20 and closely attached to the cooling-air radiator 33 to induce cold air toward the main conduit 42. The main conduit 42 is mounted in an endless groove 111 in the inner lining 11 around the inside wall of the helmet body 10. The manifolds 43 are respectively extending from the main conduit 42 at different locations, each having an air outlet 431 for delivering cooling air to the holding space 14 of the helmet body 10. The mini fan 41 according to this embodiment is an air blower that absorbs cold temperature from the cold side of the cooling-air radiator 33 and blow cold air toward the inside of the main conduit 42.

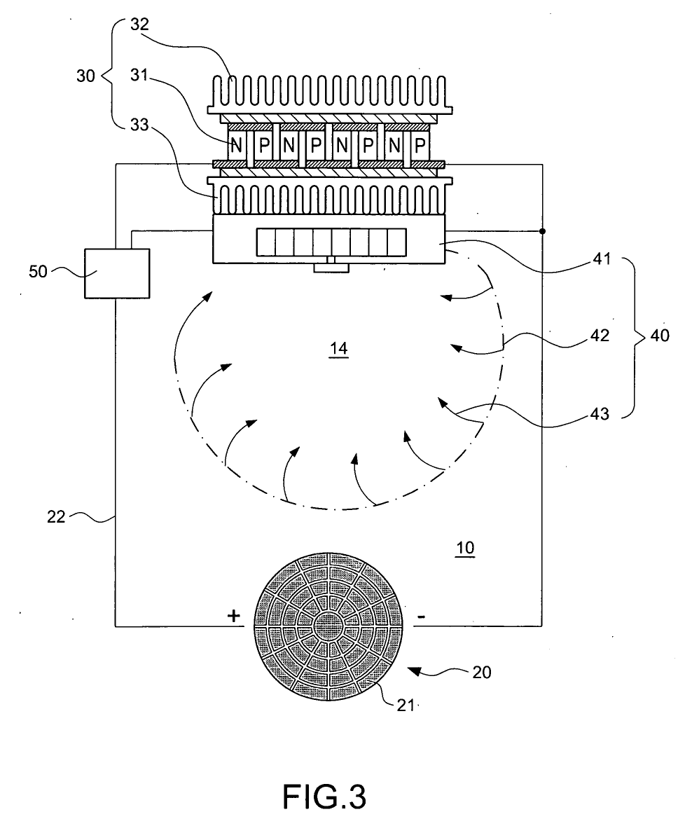

Referring to FIG. 3 again, the solar cell module 20 converts the energy of sunlight into electric energy for the working of the thermoelectric cooling module 30. When the light of the sun is getting stronger, the electric current that is produced by the solar cell module 20 will become relatively higher, and the cooling power of the thermoelectric cooling chip 31 will be relatively stronger. During the operation of the thermoelectric cooling chip 31, the mini fan 41 induces cold air toward the main conduit 42, enabling cold air to be delivered through the manifolds 43 into the inside space 14 of the helmet body 10, thereby comforting the user's head. When the intensity of sunlight is reduced, the output electric energy of the solar cell module 20 is relatively reduced, and the cooling power of the thermoelectric cooling chip 31 is relatively lowered. However, when the intensity of sunlight is low, the inside space 14 of the helmet body 10 is less hot, and the convection of air produced by the currents of air from the mini fan 41 at this time is sufficient to lower the temperature of the inside space 14 of the helmet body 10.

Further, an auto switch 50 is installed in between the power output terminal 22 of the solar cell module 20 and the thermoelectric cooling chip 31 of the thermoelectric cooling module 30, and adapted to control the output of electric energy from the power output terminal 22 to the thermoelectric cooling chip 31 subject to the detection of a current/voltage sensor (not shown), i.e. , when the value of electric current/voltage at the power output terminal 22 dropped below a predetermined level, the auto switch 50 immediately switches off the circuit between the solar cell module 20 and the thermoelectric cooling chip 31 of the thermoelectric cooling module 30, however the circuit between the power output terminal 22 and the mini fan 41 is kept closed.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A solar power-operated cooling helmet comprising:
a helmet body, said helmet body having an inner lining mounted in an inside wall thereof;
a flat solar cell module mounted in a top wall of said helmet body, said flat solar cell module comprising a silicon chip adapted to convert the energy of sunlight into electric energy;
a thermoelectric cooling module mounted in said helmet body, said thermoelectric cooling module comprising a thermoelectric cooling chip electrically connected to said power output terminal, said thermoelectric cooling chip having a hot side exposed to the outside of said helmet body and a cold side suspending inside said helmet body, a heat sink bonded to the hot side of said thermoelectric cooling chip, and a cooling-air radiator bonded to the cold side of said thermoelectric cooling chip; and
a cooling air delivery unit mounted inside said inner lining of said helmet body, said cooling air delivery unit comprising a main conduit mounted inside said inner lining around the inside wall of said helmet body, a mini fan electrically connected to said power output terminal of said thermoelectric cooling module adjacent to said cold-air radiator and adapted to induce cold air toward said main conduit, and a plurality of manifolds respectively extending from said main conduit and adapted to deliver cold air from said main conduit to the inside space of said helmet body.

2. The solar power-operated cooling helmet as claimed in claim 1, wherein said helmet body has a front opening, which accommodates said thermoelectric cooling chip.

3. The solar power-operated cooling helmet as claimed in claim 1, wherein said inner lining has an endless inside groove extending around the inside wall of said helmet body for accommodating said main conduit.

4. The solar power-operated cooling helmet as claimed in claim 1, wherein said inner lining is made out of sponge and foam material.

5. The solar power-operated cooling helmet as claimed in claim 1, further comprising switch means installed in said power output terminal of said solar cell module and adapted to detect the current/voltage level at said power output terminal and to control the supply of electric energy from said power output terminal to said thermoelectric cooling chip and said mini fan subject to the detection result.
